(19) United States
(12) Patent Application Publication
(10) Pub. No.: US 2025/0210559 A1
(43) Pub. Date: Jun. 26, 2025

(54) PACKAGING DEVICE AND MANUFACTURING METHOD THEREOF

(71) Applicant: Innolux Corporation, Miaoli County (TW)

(72) Inventors: Kuo-Shun Tsai, Miaoli County (TW); Hung-I Tseng, Miaoli County (TW); Po-Yun Hsu, Miaoli County (TW); Chia-Chi Ho, Miaoli County (TW); Jeng-Nan Lin, Miaoli County (TW); Ker-Yih Kao, Miaoli County (TW)

(73) Assignee: Innolux Corporation, Miaoli County (TW)

(21) Appl. No.: 18/963,697

(22) Filed: Nov. 28, 2024

Related U.S. Application Data
(60) Provisional application No. 63/614,664, filed on Dec. 25, 2023.

(30) Foreign Application Priority Data
Aug. 8, 2024 (CN) 202411087024.5

(51) Int. Cl. H01L 23/00; H01L 21/3105

(52) U.S. Cl. CPC H01L 24/08; H01L 21/31053; H01L 24/05; H01L 24/13; H01L 2224/05541; H01L 2224/08258; H01L 2224/13023; H01L 2924/3511

(57) ABSTRACT

A packaging device and a manufacturing method thereof are provided. The packaging device includes an electronic unit, a conductive layer, a buffer layer, an insulation layer, and a first circuit structure. The electronic unit includes a pad. The conductive layer is disposed on the pad. The buffer layer is disposed on the conductive layer. The insulation layer surrounds the electronic unit and the buffer layer. The first circuit structure is electrically connected to the electronic unit. A part of the conductive layer is located between the electronic unit and the buffer layer, and an activity of the conductive layer is less than an activity of the pad.

### CROSS-REFERENCE TO RELATED APPLICATION

This application claims the priority benefit of U.S. provisional application Ser. No. 63/614,664, filed on Dec. 25, 2023, and China application serial no. 202411087024.5, filed on Aug. 8, 2024. The entirety of each of the above-mentioned patent applications is hereby incorporated by reference herein and made a part of this specification.

### BACKGROUND

### Technical Field

The disclosure relates to a semiconductor device and a manufacturing method thereof, and more particularly to a packaging device and a manufacturing method thereof.

### Description of Related Art

Electronic devices include power modules, semiconductor packaging modules, sensing modules, etc., and usually have high electrical requirements. The packaging module needs to be stacked with multiple film layers, such as including a circuit structure to be electrically connected to a chip. However, in the incoming materials of wafers of the packaging module, more than 80% of the I/O conductive pads of the wafers adopt metal pads, such as aluminum pads or copper pads. The I/O conductive pad is easily affected by the external environment or subsequent stacking materials, which may cause the surface of the I/O conductive pad to be oxidized or contaminated with impurities, thereby causing contact resistance to be high or unstable. Therefore, how to stabilize the contact resistance of each film layer has become one of the important topics at present.

### SUMMARY

The disclosure provides a packaging device and a manufacturing method thereof, which can have improved electrical reliability.

According to an embodiment of the disclosure, a packaging device includes an electronic unit, a conductive layer, a buffer layer, an insulation layer, and a first circuit structure. The electronic unit includes a pad. The conductive layer is disposed on the pad. The buffer layer is disposed on the conductive layer. The insulation layer surrounds the electronic unit and the buffer layer. The first circuit structure is electrically connected to the electronic unit. A part of the conductive layer is located between the electronic unit and the buffer layer, and an activity of the conductive layer is less than an activity of the pad.

According to an embodiment of the disclosure, a manufacturing method of a packaging device includes the following steps. An electronic unit including a pad is provided. A conductive layer is formed on the pad. A buffer layer is formed on the conductive layer. An insulation layer is formed to surround the electronic unit and the buffer layer. A first circuit structure is formed to be electrically connected to the electronic unit. A part of the conductive layer is located between the electronic unit and the buffer layer, and an activity of the conductive layer is less than an activity of the pad.

Based on the above, in the embodiments of the disclosure, the conductive layer is disposed on the pad, and the activity of the conductive layer is less than the activity of the pad, which means that an oxidative capacity of the conductive layer is less than an oxidative capacity of the pad, that is, the conductive layer is less susceptible to oxidation than the pad, which can effectively reduce the influence of an organic material on the pad to reduce/stabilize the contact resistance of the pad, thereby enabling the packaging device of the disclosure to have improved electrical reliability.

In order for the features and advantages of the disclosure to be more comprehensible, the following specific embodiments are described in detail in conjunction with the drawings.

### BRIEF DESCRIPTION OF THE DRAWINGS

FIG. 1A to FIG. 1F are cross-sectional schematic views of a manufacturing method of a packaging device according to an embodiment of the disclosure.

FIG. 2A to FIG. 2C are cross-sectional schematic views of a manufacturing method of a packaging device according to another embodiment of the disclosure.

FIG. 2D is a cross-sectional schematic view of a packaging device according to an embodiment of the disclosure.

FIG. 3A to FIG. 3C are cross-sectional schematic views of a manufacturing method of a packaging device according to another embodiment of the disclosure.

FIG. 3D is a cross-sectional schematic view of a packaging device according to an embodiment of the disclosure.

FIG. 4 to FIG. 10 are cross-sectional schematic views of a packaging device according to multiple embodiments of the disclosure.

### DESCRIPTION OF THE EMBODIMENTS

The disclosure may be understood through referring to the following detailed description in conjunction with the drawings. It should be noted that in order to facilitate the understanding by the reader and the conciseness of the drawings, multiple drawings in the disclosure only depict a part of an electronic device, and specific elements in the drawings are not drawn according to actual scale. In addition, the number and the size of each element in the drawings are only for illustration and are not intended to limit the scope of the disclosure.

Throughout the specification and the appended claims of the disclosure, certain words are used to refer to specific elements. Persons skilled in the art should understand that electronic device manufacturers may refer to the same elements by different names. The disclosure does not intend to distinguish the elements with the same function but different names.

In the following specification and claims, words such as “containing” and “comprising” are open-ended words, which should be interpreted as “including but not limited to . . . ”.

In addition, relative terms such as “below” or “bottom portion” and “above” or “top portion” may be used in the embodiments to describe the relative relationship of one element to another element of the drawings. It should be understood that if a device in the drawings is turned upside down, elements described as “below” will become elements described as “above”.

In some embodiments of the disclosure, terms related to bonding and connection, such as “connection” and “interconnection”, unless otherwise defined, may refer to that two structures are directly in contact or may also refer to that two structures that are not directly (indirectly) in contact, wherein there is another structure provided between the two structures. Also, the terms related to bonding and connection may also include the case where two structures are both movable or two structures are both fixed. Furthermore, the term “coupling” includes the transfer of energy between two structures through means of direct or indirect electrical connection or the transfer of energy between two separate structures by means of mutual induction.

It should be understood that when an element or a film layer is referred to as being “on” or “connected to” another element or film layer, the element may be directly on the other element or film layer or directly connected to the other element or film layer, or there is an intervening element or film layer between the two (indirect case). In contrast, when an element is referred to as being “directly on” or “directly connected to” another element or film layer, there is no intervening element or film layer between the two.

The terms “about”, “equal to”, “equivalent” or “same”, “substantially”, or “roughly” are generally interpreted as within 20% of a given value or range, or interpreted as within 10%, 5%, 3%, 2%, 1%, or 0.5% of the given value or range.

As used herein, the terms “film” and/or “layer” may refer to any continuous or discontinuous structure and material (for example, a material deposited by a method of the disclosure). For example, the film and/or the layer may include a two-dimensional material, a three-dimensional material, nanoparticles, or even a part of or a complete molecular layer, a part of or a complete atomic layer, or atomic and/or molecular clusters. The film or the layer may contain a material or a layer having pinholes, which may be at least partially continuous.

Although the terms first, second, third . . . may be used to describe various constituent elements, the constituent elements are not limited by the terms. The terms are only used to distinguish a single constituent element from other constituent elements in the specification. The same terms may not be used in the claims, but replaced by first, second, third . . . according to the order in which the elements are declared in the claims. Therefore, in the following specification, a first constituent element may be a second constituent element in the claims.

Unless otherwise defined, all terms (including technical and scientific terms) used herein have the same meaning as commonly understood by persons skilled in the art to which the disclosure belongs. It should be understood that the terms, such as the terms defined in commonly used dictionaries, should be interpreted as having meanings consistent with the prior art and the background or context of the disclosure, and should be interpreted in an idealized or overly formal manner, unless specifically defined herein.

It should be noted that in the following embodiments, the technical features of several different embodiments may be replaced, reorganized, and mixed to complete other embodiments without departing from the spirit of the disclosure.

An electronic device of the disclosure may include a power module, a semiconductor device, a semiconductor packaging device, a display device, an antenna device, a sensing device, a light emitting device, or a splicing device, but not limited thereto. The electronic device may include a bendable or flexible electronic device. The electronic device may include an electronic element. The electronic element may include a passive element, an active element, or a combination of the above, such as a capacitor, a resistor, an inductor, a variable capacitor, a filter, a diode, a transistor, a sensor, a microelectromechanical system (MEMS) element, and a liquid crystal chip, but not limited thereto. The diode may include a light emitting diode or a non-light emitting diode. The diode includes a P-N junction diode, a PIN diode, or a constant current diode. The light emitting diode may include, for example, an organic light emitting diode (OLED), a mini LED, a micro LED, a quantum dot LED, fluorescence, phosphor, other suitable materials, or a combination of the above, but not limited thereto. The sensor may include, for example, a capacitive sensor, an optical sensor, an electromagnetic sensor, a fingerprint sensor (FPS), a touch sensor, an antenna, a pen sensor, etc., but not limited thereto. The following description will take the display device as the electronic device to illustrate the disclosure, but the disclosure is not limited thereto. According to an embodiment of the disclosure, a manufacturing method of the electronic device provided may be applied, for example, to a wafer-level package (WLP) process or a panel-level package (PLP) process and may adopt a chip first process or a chip last/RDL first process, which will be further described in detail below. The electronic device referred to in the disclosure may include a system on package (SoC), a system in package (SiP), an antenna in package (AiP), or a combination of the above, but not limited thereto.

In the disclosure, length, width, thickness, height, or area, or distance or spacing between components may be measured by adopting an optical microscope (OM), a scanning electron microscope (SEM), an α-step, an ellipsometer, or other suitable manners. Specifically, according to some embodiments, a cross-sectional structural image of a component to be measured may be obtained using the scanning electron microscope, and the length, width, thickness, height, or area of each component, or the distance or spacing between the components may be measured, but the disclosure is not limited thereto.

Reference will now be made in detail to the exemplary embodiments of the disclosure, and examples of the exemplary embodiments are illustrated in the drawings. Wherever possible, the same reference numerals are used in the drawings and the description to refer to the same or similar parts.

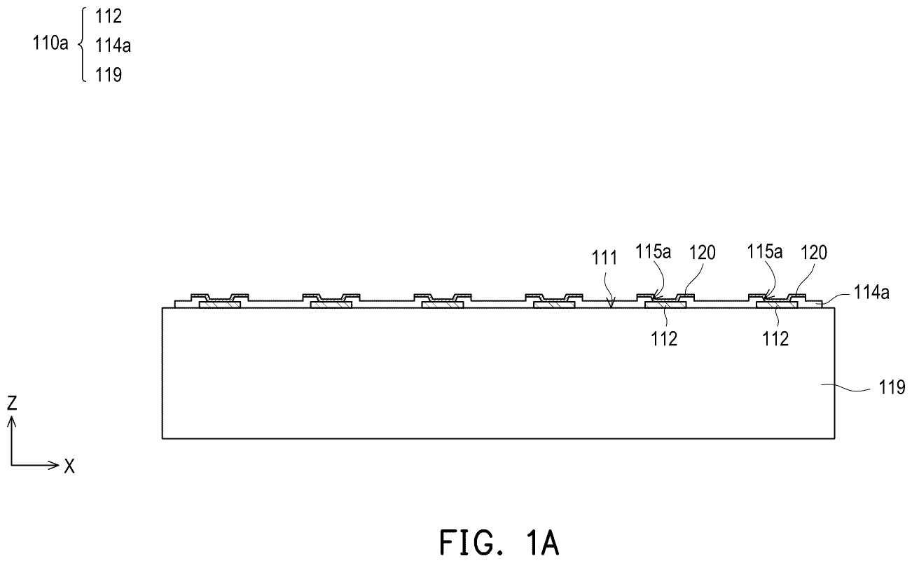

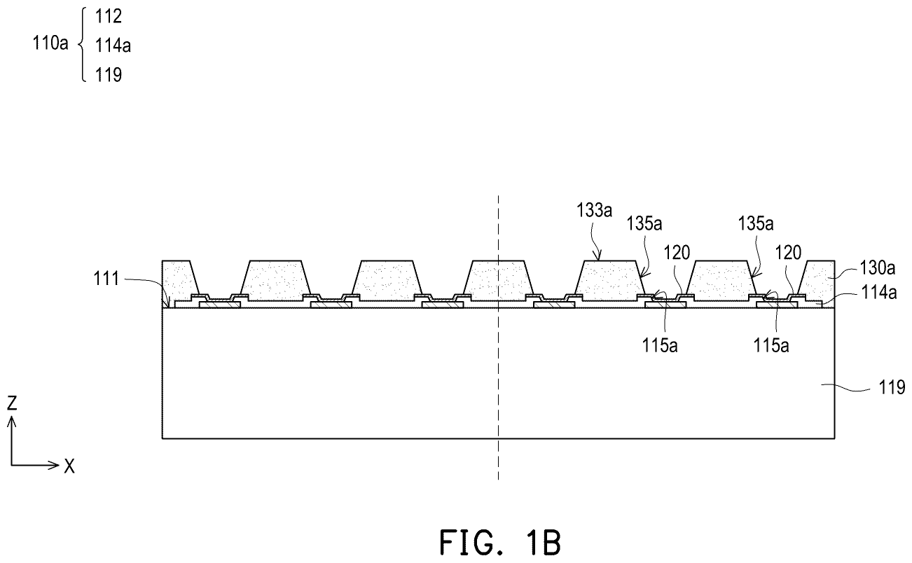

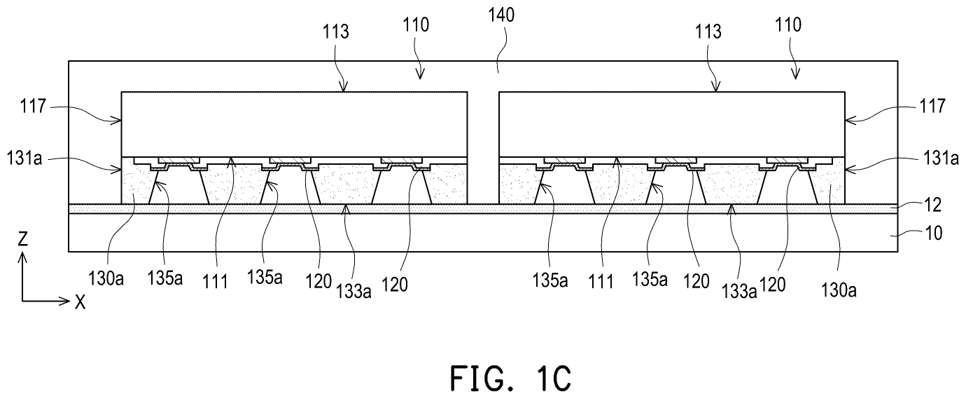

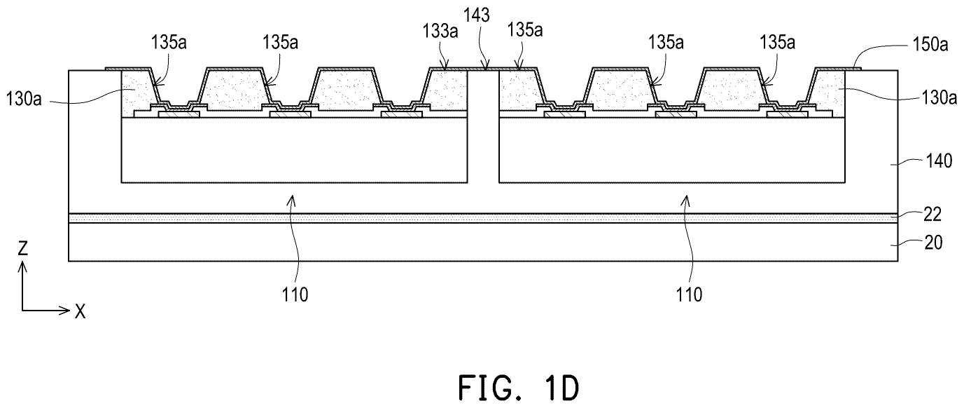

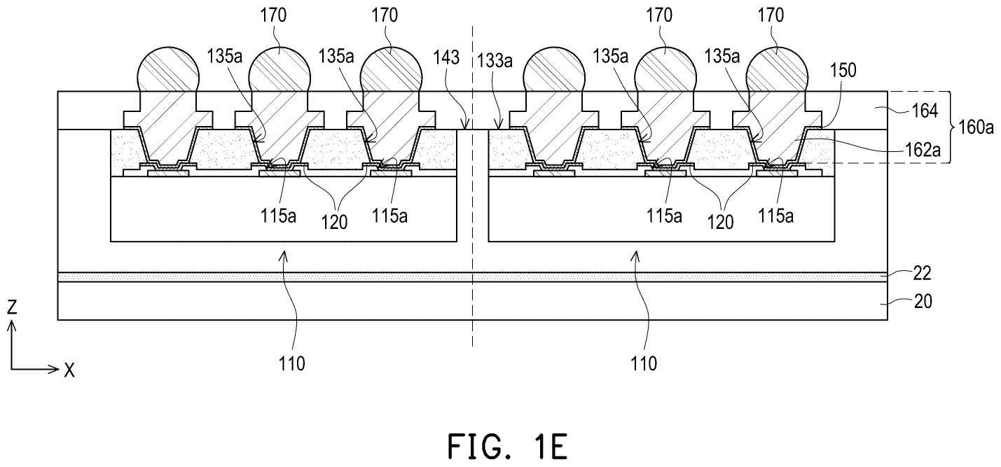

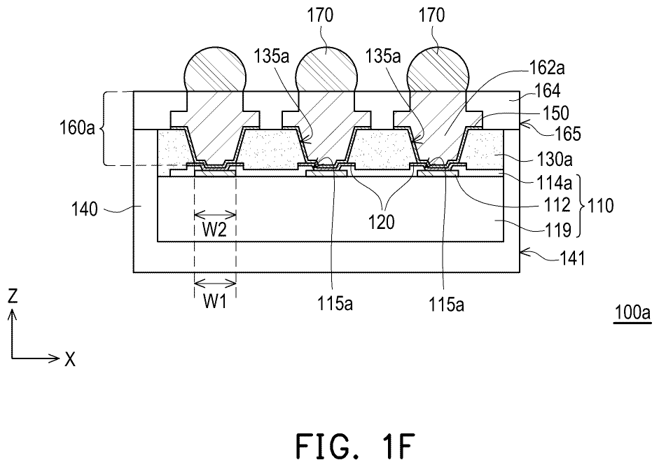

FIG. 1A to FIG. 1F are cross-sectional schematic views of a manufacturing method of a packaging device according to an embodiment of the disclosure. Please refer to FIG. 1A first. Regarding the manufacturing method of the packaging device of the embodiment, first, an electronic unit 110a including a pad 112 is provided. In an embodiment, the electronic unit 110a is, for example, a wafer or a semiconductor structure, wherein the pads 112 are separately disposed on a base layer 119 of the electronic unit 110a and are located on an active surface 111. In an embodiment, the material of the pad 112 is a conductive material, such as aluminum, copper, an aluminum-copper alloy, or other suitable conductive materials, but not limited thereto. The pad 112 referred to in the disclosure may be an endpoint for receiving or outputting signals of the electronic unit 110a, such as an I/O pad. The base layer 119 referred to in the disclosure may include glass, silicon carbide (SiC), gallium nitride (GaN), or a silicon-containing material.

Next, please refer to FIG. 1A. The electronic unit 110a may further include a protective layer 114a, wherein the protective layer 114a includes a first opening 115a, and the first opening 115a exposes at least part of the pad 112. The protective layer 114a is formed on the base layer 119, and the protective layer 114a covers a part of the pad 112 and a part of the base layer 119. In other words, a part of the base layer 119 is not covered by the protective layer 114a, and the first opening 115a of the protective layer 114a exposes at least part of the pad 112. In an embodiment, the protective layer 114a may be, for example, a suitable insulating material, such as silicon nitride, silicon oxide, silicon oxynitride, dielectric, a polymer, an organic material, and polyimide, which is not limited herein. According to some embodiments, the protective layer 114a may include a multi-layer stack. For example, silicon oxide is formed between the pad 112 and silicon oxynitride or silicon oxide is formed between the pad 112 and silicon nitride, wherein when the protective layer 114a is a multi-layer stacked structure, the thickness of silicon oxide is greater than or equal to the thickness of silicon nitride, so as to reduce the stress of subsequent film layers on the electronic unit 110a, but not limited thereto.

Next, please refer to FIG. 1A. A conductive layer 120 is formed on the pad 112, wherein the conductive layer 120 covers at least part of the pad 112. The conductive layer 120 corresponds to the pad 112, wherein the conductive layer 120 is located on an inner wall of the first opening 115a of the protective layer 114a, contacts the pad 112 exposed by the first opening 115a, and extends onto a surface of the protective layer 114a away from the base layer 119. In an embodiment, the conductive layer 120 directly contacts the pad 112. In an embodiment, a conductive material layer (not shown) is first formed on the pad 112 and the protective layer 114a. Then, the conductive material layer is patterned to expose a part of the protective layer 114a to form the conductive layer 120 corresponding to the pad 112 and extending onto a part of the protective layer 114a. In an embodiment, the material of the conductive layer 120 includes titanium, copper, tantalum, titanium copper, tantalum copper, nickel, gold, platinum, silver, or indium tin oxide (ITO), but not limited thereto. In an embodiment, the thickness of the conductive layer 120 is, for example, 0.1 mm to 2 mm. In an embodiment, the conductive layer 120 may be a single-layer structural layer or a multi-layer structural layer, which is not limited herein. Particularly, in the embodiment, the activity of the conductive layer 120 is less than the activity of the pad 112, which means that the oxidative capacity of the conductive layer 120 is less than the oxidative capacity of the pad 112, that is, the conductive layer 120 is less susceptible to oxidation than the pad 112. The oxidative capacity referred to in the disclosure is comparison of reactivity of a component to water, gas, or a solvent at an ambient temperature of about 23° C. to 26° C.

Next, please refer to FIG. 1B. A buffer layer 130a is formed on the conductive layer 120, wherein the buffer layer 130a covers the protective layer 114a of the electronic unit 110a and a part of the conductive layer 120, and a part of the conductive layer 120 is located between the electronic unit 110a and the buffer layer 130a. In an embodiment, the buffer layer 130a contacts the base layer 119 of the electronic unit 110a. In an embodiment, a buffer material layer (not shown) is first formed on the conductive layer 120 and the protective layer 114a of the electronic unit 110a, and the buffer material layer is then patterned to form the buffer layer 130a exposing a part of the conductive layer 120. The patterning step includes surface treatment steps such as yellow light, dry etching, development, laser, wet etching, and plasma processing, but not limited thereto. At this time, the buffer layer 130a forms a second opening 135a overlapping with the first opening 115a, and the second opening 135a exposes a part of the conductive layer 120. In an embodiment, the diameter of the second opening 135a gradually decreases from being away from the electronic unit 110a toward the direction close to the electronic unit 110a, but not limited thereto.

In an embodiment, the material of the buffer layer 130a is, for example, an organic material, such as polyimide (PI), photosensitive polyimide (PSPI), epoxy, a polymer, or an Ajinomoto build-up film (ABF); or an inorganic material, such as silicon dioxide, titanium dioxide or aluminum oxide, but not limited thereto. In an embodiment, the buffer layer 130a may further include a filler, wherein the particle size of the filler is, for example, 0.05 mm to 10 mm. In an embodiment, the coefficient of thermal expansion (CTE) of the buffer layer 130a is, for example, between 5 ppm/C and 50 ppm/C. In an embodiment, the Young's modulus of the buffer layer 130a is, for example, between 3 GPa and 20 GPa. In an embodiment, the tensile strength of the buffer layer 130a is, for example, between 50 MPa and 110 MPa.

Next, please refer to FIG. 1B and FIG. 1C at the same time. A singulation process is performed to cut the electronic unit 110a and the buffer layer 130a to form multiple electronic units 110 separated from each other and the conductive layer 120 and the buffer layer 130a thereon. In an embodiment, the electronic unit 110 may include a passive element or an active element, such as a capacitor, a resistor, an inductor, a variable capacitor, a filter, a diode, a transistor, a sensor, a microelectromechanical system (MEMS) element, a chip, and a liquid crystal chip, but not limited thereto.

Next, the above structure is attached onto an adhesive layer 12 of a substrate 10 with the active surface 111 of the electronic unit 110 facing downward, that is, a chip first/face down manner, wherein a top surface 133a of the buffer layer 130a directly contacts the adhesive layer 12, and the adhesive layer 12 covers the second opening 135a of the buffer layer 130a. According to some embodiments, the above structure may also be attached onto the adhesive layer 12 of the substrate 10 with the active surface 111 of the electronic unit 110 facing upward for subsequent steps, that is, a chip first/face up manner.

Next, please refer to FIG. 1C. The insulation layer 140 is formed to surround the electronic unit 110 and the buffer layer 130a. In an embodiment, the insulation layer 140 covers and encapsulates a back surface 113 and a surrounding surface 117 of the electronic unit 110 and a surrounding surface 131a of the buffer layer 130a. In an embodiment, in a cross-sectional view, the insulation layer 140 surrounding the electronic unit 110 and the buffer layer 130a means that the insulation layer 140 directly contacts at least one side surface of the electronic unit 110 and the buffer layer 130a. In an embodiment, the material of the insulation layer 140 is, for example, a polymer or an epoxy molding compound (EMC), wherein the insulation layer 140 is formed by, for example, a molding process, but not limited thereto. According to some embodiments, along a direction Z, the thickness of the insulation layer 140 located on the back surface 113 of the electronic unit 110 may be greater than the thickness of the base layer 119 of the electronic unit 110. Warping may be reduced through the above design, but not limited thereto.

Next, please refer to FIG. 1C and FIG. 1D at the same time. The structure of FIG. 1C is flipped and attached onto an adhesive layer 22 on a substrate 20, and the substrate 10 and the adhesive layer 12 thereon are removed to expose the top surface 133a and the second opening 135a of the buffer layer 130a.

Next, please refer to FIG. 1D. A seed layer 150a is formed on the buffer layer 130a and contacts the conductive layer 120. In an embodiment, the seed layer 150a directly covers an inner wall of the second opening 135a of the buffer layer 130a and overlaps with the conductive layer 120. Furthermore, the seed layer 150a directly covers the inner wall of the second opening 135a of the buffer layer 130a and directly contacts the conductive layer 120, wherein the seed layer 150a extends onto the top surface 133a of the buffer layer 130a away from the electronic unit 110 and a surface 143 of the insulation layer 140. In an embodiment, the material of the seed layer 150a is, for example, titanium, copper, aluminum, tantalum, titanium copper, tantalum copper, nickel, gold, silver, or indium tin oxide (ITO), but not limited thereto. In an embodiment, the thickness of the seed layer 150a is, for example, 0.1 mm to 2 mm. In an embodiment, the seed layer 150a may be a single-layer structural layer or a multi-layer structural layer, which is not limited herein. In an embodiment, the material of the seed layer 150a may be the same as the material of the conductive layer 120. In an embodiment, the material of the seed layer 150a may be different from the material of the conductive layer 120. According to some embodiments, a part of the seed layer 150a overlapping with the conductive layer 120 has a thickness, and the thickness of the part may be the same as or different from the thickness of the conductive layer 120. For example, the thickness of the conductive layer 120 may be less than the thickness of the seed layer 150a. Through the above design, the deposition quality of subsequent film layers may be confirmed, such as improving bonding strength, but not limited thereto. The seed layer referred to in the disclosure may, for example, improve the bonding force between film layers or allow subsequent film layers to be formed.

Afterwards, please refer to FIG. 1D and FIG. 1E. A first circuit structure 160a is formed to be electrically connected to the electronic unit 110, wherein a first metal layer 162a of the first circuit structure 160a extends into the second opening 135a and the first opening 115a. According to some embodiments, the first metal layer 162a may contact the conductive layer 120. In other words, the first metal layer 162a of the first circuit structure 160a extends into the second opening 135a and the first opening 115a and overlaps with the conductive layer 12. In an embodiment, a patterned photoresist layer (not shown) is first formed on the insulation layer 140 and the seed layer 150a. According to some embodiments, the seed layer 150a may be, for example, an electroplating seed layer, and a metal material layer (not shown) is formed on the seed layer 150a exposed by the patterned photoresist layer by electroplating, but the disclosure is not limited thereto. The seed layer 150a may also be a promoting film layer for improving the bonding force between the subsequent layer and the previous layer, but not limited thereto. Thereafter, the patterned photoresist layer and the seed layer 150a thereunder are removed to form the first metal layer 162a and a seed layer 150 thereunder. In an embodiment, the first metal layer 162a extends to be disposed on the top surface 133a of the buffer layer 130a. In an embodiment, the first circuit structure 160a may further include an insulation layer 164 covering the first metal layer 162a and the surface 143 of the insulation layer 140. Through steps such as grinding or surface treatment, the insulation layer 164 may expose at least part of the first metal layer 162a. In an embodiment, along the direction Z, there may be a spacing between a surface of the first metal layer 162a away from the electronic unit 110 and a surface 164a of the insulation layer 164 away from the electronic unit 110, wherein the spacing may be greater than 0 and less than or equal to 10 μm.

In an embodiment, the first circuit structure 160a may be a redistribution structure, wherein the redistribution structure includes at least one conductive layer and at least one insulation layer stacked along the direction Z, wherein a method for forming the redistribution structure includes a process such as yellow light, dry etching, wet etching, surface treatment, plasma surface treatment, laser, and electroplating. The surface treatment includes roughening an insulation layer surface or a conductive layer surface to improve the bonding ability thereof. The redistribution structure is a substrate or a circuit structure for extending a connection to a wider spacing or to reroute a connection to another connection with a different spacing or to serve as an electrical interface wiring between one connection and another connection. The material of the insulation layer of the redistribution structure may be, for example, polyimide (PI), photosensitive polyimide (PSPI), polybenzoxazole (PBO), epoxy, a polymer, an Ajinomoto build-up film (ABF), silicon oxynitride (SiOxNy), silicon oxide (SiOx), or silicon nitride (SiNx), but not limited thereto. The material of the insulation layer may include the same or different materials.

Next, please refer to FIG. 1E. A connector 170 is formed on the first circuit structure 160a, wherein the connector 170 is electrically connected to the first metal layer 162a of the first circuit structure 160a. In an embodiment, the material of the connector 170 may include tin, nickel, gold, silver, palladium, copper, gallium, an alloy of the above, or a combination thereof, but not limited thereto. According to some embodiments, the connector 170 is, for example, a solder ball, but not limited thereto. According to some embodiments, the connector 170 may, for example, extend into a spacing between the surface of the first metal layer 162a away from the electronic unit 110 and the surface 164a of the insulation layer 164 away from the electronic unit 110. Through the above design, the bonding force between the connector 170 and the first metal layer 162a can be improved.

Finally, please refer to FIG. 1E and FIG. 1F at the same time. The substrate 20 and the adhesive layer 22 thereon are removed, and a singulation process is performed to cut the insulation layer 140 and the insulation layer 164 of the first circuit structure 160a to form multiple packaging devices 100a (only one is schematically shown in FIG. 1F) separated from each other. At this point, the manufacturing of the packaging device 100a is completed. According to some embodiments, there may be a spacing between a surrounding surface 141 of the insulation layer 140 and a surrounding surface 165 of the insulation layer 164 of the first circuit structure 160a along a direction X, and the spacing may be greater than or equal to 0 and less than or equal to 1 μm to prevent affecting the reliability of the packaging device 100a.

In terms of structure, please refer to FIG. 1F. In the embodiment, the packaging device 100a includes the electronic unit 110, the conductive layer 120, the buffer layer 130a, the insulation layer 140, and the first circuit structure 160a. The electronic unit 110 includes the pad 112. The conductive layer 120 is disposed on the pad 112. The buffer layer 130a is disposed on the conductive layer 120. The insulation layer 140 surrounds the electronic unit 110 and the buffer layer 130a. The first circuit structure 160a is electrically connected to the electronic unit 110. A part of the conductive layer 120 is located between the electronic unit 110 and the buffer layer 130a, and the activity of the conductive layer 120 is less than the activity of the pad 112.

Specifically, in the embodiment, the electronic unit 110 further includes the protective layer 114a, wherein the protective layer 114a includes the first opening 115a to expose at least part of the pad 112, and the conductive layer 120 covers at least part of the pad 112. As shown in FIG. 1F, the protective layer 114a covers a part of the pad 112 and a part of the base layer 119 of the electronic unit 110. In other words, a part of the base layer 119 of the electronic unit 110 is not covered by the protective layer 114a, and the first opening 115a of the protective layer 114a exposes at least part of the pad 112. Furthermore, the buffer layer 130a includes the second opening 135a overlapping with the first opening 115a, wherein the first metal layer 162a of the first circuit structure 160a extends into the second opening 135a and the first opening 115a and contacts the conductive layer 120. In an embodiment, the buffer layer 130a contacts the base layer 119 of the electronic unit 110. In addition, the packaging device 100a of the embodiment further includes the seed layer 150 disposed between the first metal layer 162a and the buffer layer 130a and contacting the conductive layer 120.

Please refer to FIG. 1F. A part of the protective layer 114a of the embodiment overlaps with the pad 112, wherein a width W1 of the pad 112 may be slightly greater than or equal to a width W2 of the first opening 135a of the buffer layer 130a. The width of the second opening 135a described here is the width W2 closest to the first opening W1. Since the conductive layer 120 of the embodiment is disposed on the pad 112 and the activity of the conductive layer 120 is less than the activity of the pad 112, which means that the oxidative capacity of the conductive layer 120 is less than the oxidative capacity of the pad 112, that is, the conductive layer 120 is less susceptible to oxidation than the pad 112, which can effectively reduce the influence of the organic material (for example, the buffer layer 130a) on the pad 112 to reduce/stabilize the contact resistance of the pad 112, thereby enabling the packaging device 100a of the embodiment to have improved electrical reliability.

It should be noted that the following embodiments continue to use the reference numerals and some content of the foregoing embodiment, wherein the same reference numerals are adopted to represent the same or similar elements, and the description of the same technical content is omitted. Reference may be made to the foregoing embodiment for the description of the omitted part, which will not be repeated in the following embodiments.

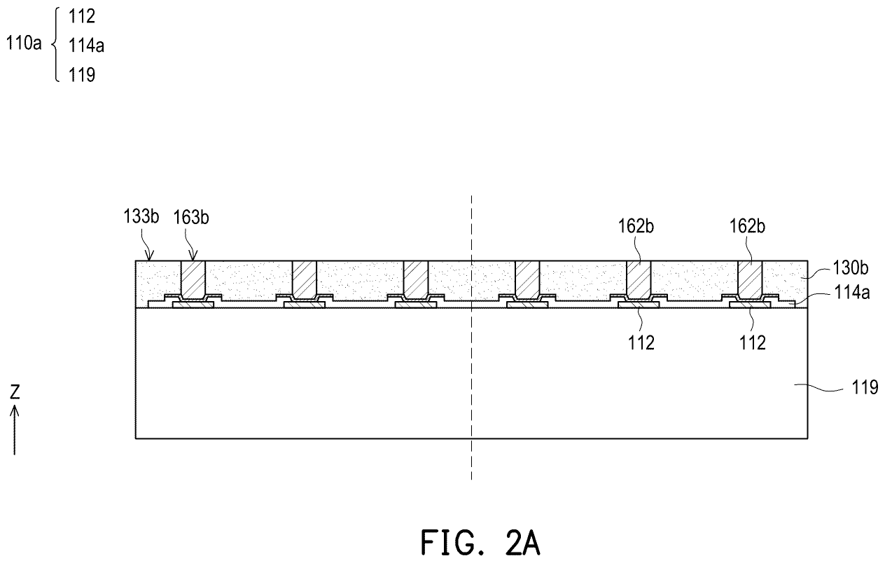

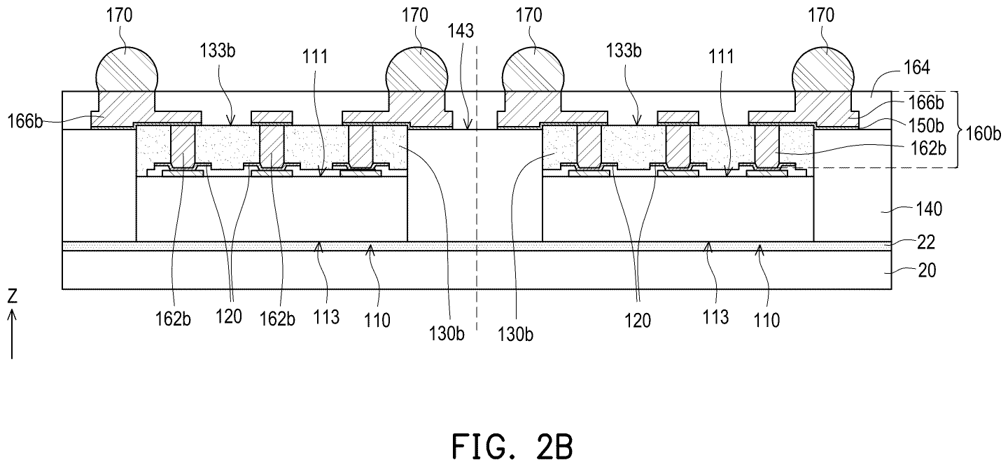

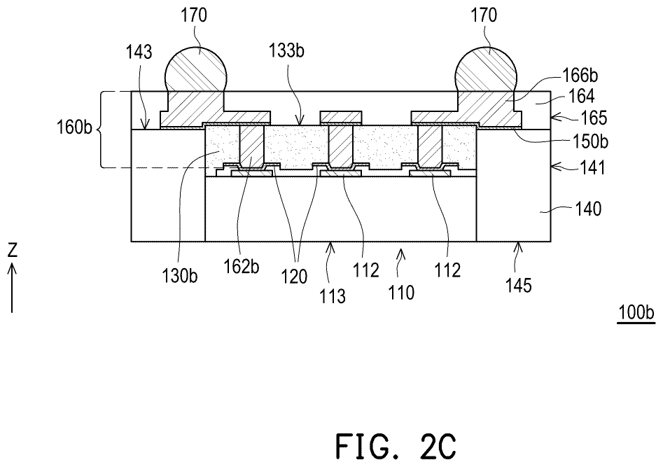

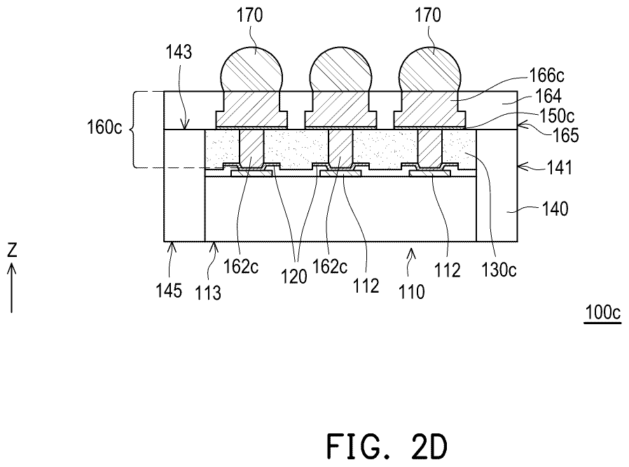

FIG. 2A to FIG. 2C are cross-sectional schematic views of a manufacturing method of a packaging device according to another embodiment of the disclosure. FIG. 2D is a cross-sectional schematic view of a packaging device according to an embodiment of the disclosure. Please refer to FIG. 1A and FIG. 2A first at the same time. The manufacturing method of the packaging device of the embodiment is similar to the manufacturing method of the packaging device described above. The difference between the two is that in the embodiment, after the step of FIG. 1A, a conductive material layer (not shown) is formed on the pad 112 and the protective layer 114a, and before the conductive material layer is patterned, a patterned photoresist layer is formed on the conductive material layer, wherein the patterned photoresist layer exposes a part of the conductive material layer corresponding to the pad 112. Next, the conductive material layer exposed by the patterned photoresist layer is used as a seed layer to electroplate a metal material layer (not shown). Thereafter, the patterned photoresist layer and the conductive material layer thereunder are removed to form a first metal layer 162b and the conductive layer 120 connecting the first metal layer 162b and the pad 112. In an embodiment, the orthographic projection area of the first metal layer 162b on the pad 112 is less than and overlaps with the pad 112.

In an embodiment, the first metal layer 162b is, for example, a conductive column, wherein the diameter of the conductive column is a constant value, but not limited thereto. In an embodiment, a surrounding surface of the first metal layer 162b may be a roughened surface, wherein the arithmetic average roughness (Ra) of the first metal layer 162b is, for example, between 0.15 μm and 1 μm. The measurement of roughening may include using a scanning electron microscope (SEM), a transmission electron microscope (TEM), etc. to observe the condition of surface undulations at the same appropriate magnification, and comparing the undulation condition by taking a unit length (for example, 10 μm). Here, “appropriate magnification” means that at least 10 undulating peaks can be seen for at least one surface under the field of view of such magnification.

Next, please refer to FIG. 2A. A buffer layer 130b is formed on the conductive layer 120, wherein the buffer layer 130b covers the protective layer 114a of the electronic unit 110a and a part of the conductive layer 120 and completely encapsulates the surrounding surface of the first metal layer 162b, and a part of the conductive layer 120 is located between the electronic unit 110a and the buffer layer 130b. In an embodiment, a buffer material layer (not shown) is first formed on the conductive layer 120 and the protective layer 114a of the electronic unit 110a and completely encapsulates the first metal layer 162b, wherein the buffer material layer contacts the base layer 119 of the electronic unit 110a. Next, a part of the buffer material layer is removed through, for example, grinding or photolithography to form the buffer layer 130b. In an embodiment, a top surface 133b of the buffer layer 130b may be flush with a surface 163b of the first metal layer 162b, but not limited thereto.

Next, please refer to FIG. 2A and FIG. 2B at the same time. A singulation process is performed to cut the electronic unit 110a and the buffer layer 130b to form multiple electronic units 110 separated from each other and the conductive layer 120 and the buffer layer 130b thereon. Next, the above structure is attached onto the adhesive layer 22 of the substrate 20, wherein the above structure is attached onto the adhesive layer 22 on the substrate 20 with the active surface 111 of the electronic unit 110 facing upward, wherein the back surface 113 of the electronic unit 110 directly contacts the adhesive layer 22.

Next, please refer to FIG. 2B. The insulation layer 140 is formed to surround the electronic unit 110 and the buffer layer 130b. In an embodiment, in a cross-sectional view, the insulation layer 140 surrounding the electronic unit 110 and the buffer layer 130b means that the insulation layer 140 directly contacts at least one side surface of the electronic unit 110 and the buffer layer 130b. In an embodiment, the insulation layer 140 completely encapsulates the electronic unit 110 and the buffer layer 130b, and a grinding process may be performed to expose the top surface 133b of the buffer layer 130b. In an embodiment, the top surface 133b of the buffer layer 130b may be flush with the surface 143 of the insulation layer 140. In an embodiment, the top surface 133b of the buffer layer 130b may be slightly higher than the surface 143 of the insulation layer 140. In an embodiment, the material of the insulation layer 140 is, for example, an epoxy molding compound (EMC), wherein the insulation layer 140 is formed by, for example, a molding process, but not limited thereto.

Next, please refer to FIG. 2B, a seed layer 150b is formed on the buffer layer 130a and a part of the surface 143 of the insulation layer 140 and extends onto the surface 163b of the first metal layer 162b. In an embodiment, the material of the seed layer 150b is, for example, titanium, copper, aluminum, tantalum, titanium copper, tantalum copper, nickel, gold, silver, or indium tin oxide (ITO), but not limited thereto. In an embodiment, the thickness of the seed layer 150b is, for example, 0.2 mm to 2 mm. In an embodiment, the seed layer 150b may be a single-layer structural layer or a multi-layer structural layer, which is not limited herein. In an embodiment, the material of the seed layer 150b may be the same as the material of the conductive layer 120. In an embodiment, the material of the seed layer 150b may be different from the material of the conductive layer 120.

Next, please refer to FIG. 2B, a second metal layer 166b and the insulation layer 164 are formed on the surface 143 of the insulation layer 140, wherein the second metal layer 166b is disposed corresponding to the seed layer 150b, and the insulation layer 164 covers the second metal layer 166b and the insulation layer 140. In an embodiment, viewing from a cross-section, the second metal layer 166b extends from the buffer layer 130b to be disposed on the insulation layer 140, wherein the distribution area of the second metal layer 166b is greater than the distribution area of the first metal layer 162b, that is, the first metal layer 162b and the second metal layer 166b form a fan-out circuit. In an embodiment, the first metal layer 162b, the insulation layer 164, the seed layer 150b, and the second metal layer 166b may be defined as a first circuit structure 160b, wherein the first circuit structure 160b is electrically connected to the electronic unit 110.

Next, please refer to FIG. 2B. The connector 170 is formed on the first circuit structure 160b, wherein the connector 170 is electrically connected to the second metal layer 166b of the first circuit structure 160b. In an embodiment, the connector 170 is, for example, a solder ball, but not limited thereto.

Finally, please refer to FIG. 2B and FIG. 2C at the same time. The substrate 20 and the adhesive layer 22 thereon are removed to expose the back surface 113 of the electronic unit 110, wherein the back surface 113 of the electronic unit 110 is flush with a surface 145 of the insulation layer 140. Next, a singulation process is performed to cut the insulation layer 140 and the insulation layer 164 of the first circuit structure 160b, so that the surrounding surface 141 of the insulation layer 140 is flush with the surrounding surface 165 of the insulation layer 164 of the first circuit structure 160b to form multiple packaging devices 100b (only one is schematically shown in FIG. 2C) separated from each other. At this point, the manufacturing of the fan-out packaging device 100b is completed.

Please refer to FIG. 2C and FIG. 2D at the same time. Through the manufacturing method of the packaging device, a fan-in packaging device 100c may also be formed, wherein viewing from a cross-section, a second metal layer 166c is only disposed on a buffer layer 130c and is disposed corresponding to a first metal layer 162c. In other words, the first metal layer 162c, the insulation layer 164, a seed layer 150c, and the second metal layer 166c may be defined as a fan-in first circuit structure 160c.

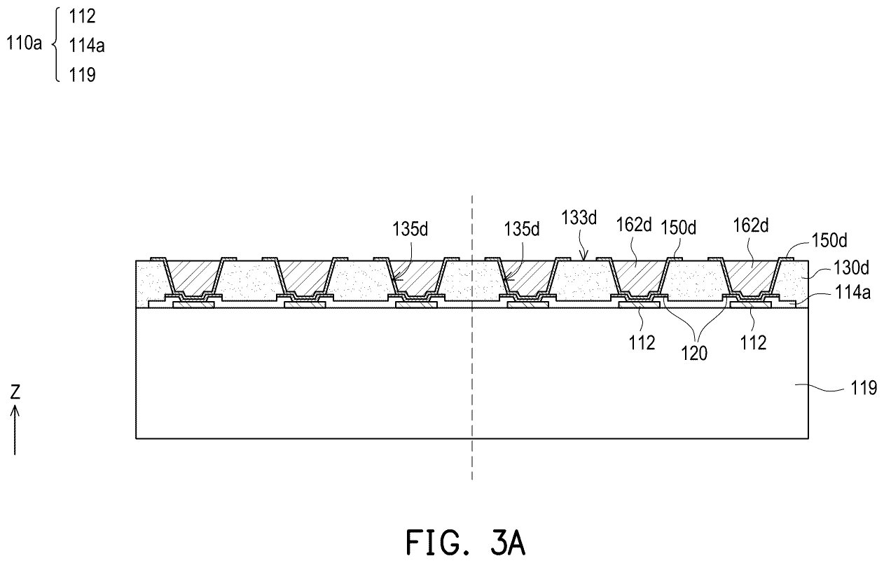

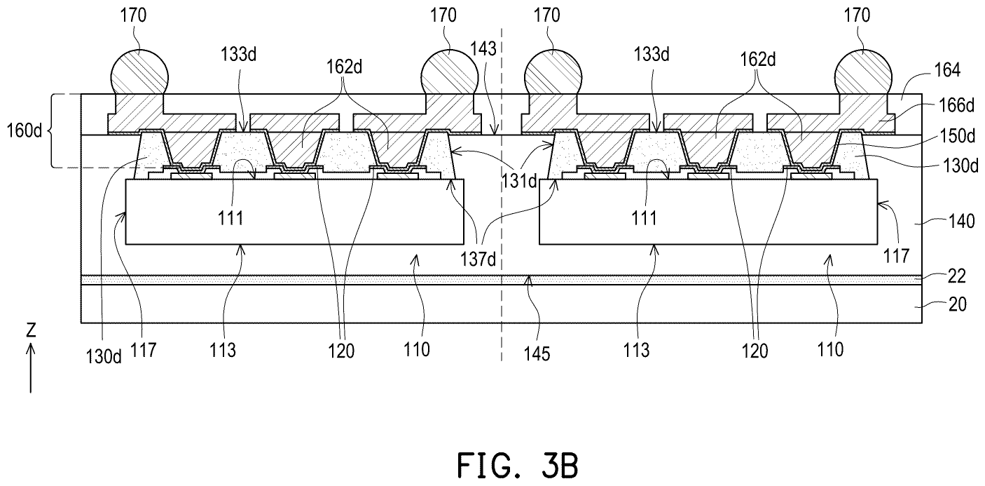

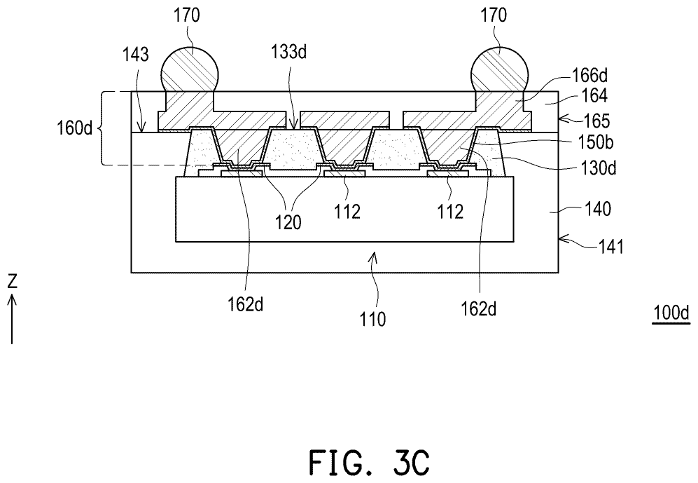

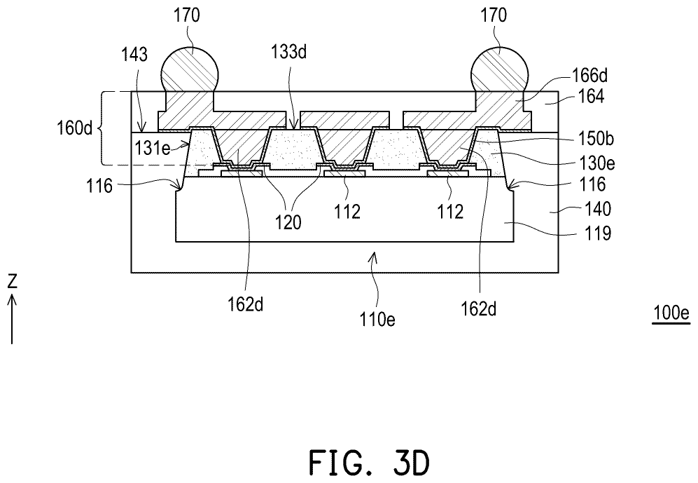

FIG. 3A to FIG. 3C are cross-sectional schematic views of a manufacturing method of a packaging device according to another embodiment of the disclosure. FIG. 3D is a cross-sectional schematic view of a packaging device according to an embodiment of the disclosure. Please refer to FIG. 1B and FIG. 3A first at the same time. The manufacturing method of the packaging device of the embodiment is similar to the manufacturing method of the packaging device described above. The difference between the two is that in the embodiment, after the step of FIG. 1B, that is, after forming a buffer layer 130d on the conductive layer 120, a seed layer 150d is formed on the buffer layer 130d and contacts the conductive layer 120, wherein the seed layer 150d directly covers a second opening 135d of the buffer layer 130d and extends onto a top surface 133d. In an embodiment, the material of the seed layer 150d is, for example, titanium, copper, aluminum, tantalum, nickel, gold, silver, or indium tin oxide (ITO), but not limited thereto. In an embodiment, the thickness of the seed layer 150d is, for example, 0.2 mm to 2 mm. In an embodiment, the seed layer 150d may be a single-layer structural layer or a multi-layer structural layer, which is not limited herein. In an embodiment, the material of the seed layer 150d may be the same as the material of the conductive layer 120. In an embodiment, the material of the seed layer 150d may be different from the material of the conductive layer 120.

Next, please refer to FIG. 3A. A first metal layer 162d is formed on the seed layer 150d. In an embodiment, the first metal layer 162d is, for example, a conductive column, wherein the diameter of the conductive column gradually decreases from the top surface 133d of the buffer layer 130d toward the direction of the electronic unit 110a, but not limited thereto. In an embodiment, the seed layer 150d is used as an electroplating seed layer, and the first metal layer 162d is formed on the seed layer 150d by electroplating.

Next, please refer to FIG. 3A and FIG. 3B at the same time. A singulation process is performed to cut the electronic unit 110a and the buffer layer 130d to form multiple electronic units 110 separated from each other and the conductive layer 120 and the buffer layer 130d thereon. After the cutting process, the buffer layer 130d has a top surface 133d, a bottom surface 137d, and a surrounding surface 131d obliquely connecting the top surface 133d and the bottom surface 137d. In other words, the surrounding surface 131d of the buffer layer 130d of the embodiment is an inclined surface. The inclination referred to in the disclosure means that, in a cross-sectional schematic view, an included angle between an extension line of a surface and a normal direction of an electronic device is greater than 0.

Next, the above structure is attached onto an adhesive layer (not shown) of a substrate (not shown), wherein the above structure is attached onto the adhesive layer of the substrate with the active surface 111 of the electronic unit 110 facing downward. Next, the insulation layer 140 is formed to surround the electronic unit 110 and the buffer layer 130d. In an embodiment, the insulation layer 140 completely covers and encapsulates the back surface 113 and the surrounding surface 117 of the electronic unit 110 and the surrounding surface 131d of the buffer layer 130d.

Next, please refer to FIG. 3B. The above structure is flipped and attached onto the adhesive layer 22 on the substrate 20, which means that the active surface 111 of the electronic unit 110 faces upward, and the surface 145 of the insulation layer 140 is directly adhered onto the adhesive layer 22, and the substrate and the adhesive layer thereon are removed to expose the top surface 133d of the buffer layer 130d and the first metal layer 162d located in the second opening 135d of the buffer layer 130d. In an embodiment, the top surface 133d of the buffer layer 130d may be flush with the surface 143 of the insulation layer 140. In an embodiment, the top surface 133d of the buffer layer 130d may be slightly higher than the surface 143 of the insulation layer 140.

Next, please refer to FIG. 3B. A second metal layer 166d and the insulation layer 164 are formed on the surface 143 of the insulation layer 140, wherein viewing from a cross-section, the second metal layer 166d is connected to the first metal layer 162d and extends to be disposed on the buffer layer 130d and the insulation layer 140, and the distribution area of the second metal layer 166d is greater than the distribution area of the first metal layer 162d, that is, the first metal layer 162d and the second metal layer 166d form a fan-out circuit. The insulation layer 164 covers the second metal layer 166d and the insulation layer 140. In an embodiment, the first metal layer 162d, the insulation layer 164, the seed layer 150d, and the second metal layer 166d may be defined as a first circuit structure 160d, wherein the first circuit structure 160d is electrically connected to the electronic unit 110. In an embodiment, a seed layer may also be disposed between the second metal layer 166d and the buffer layer 130d and the insulation layer 140.

Next, please refer to FIG. 3B. The connector 170 is formed on the first circuit structure 160d, wherein the connector 170 is electrically connected to the second metal layer 166d of the first circuit structure 160d. In an embodiment, the connector 170 is, for example, a solder ball, but not limited thereto.

Finally, please refer to FIG. 3B and FIG. 3C at the same time. The substrate 20 and the adhesive layer 22 thereon are removed, and a singulation process is performed to cut the insulation layer 140 and the insulation layer 164 of the first circuit structure 160d, so that the surrounding surface 141 of the insulation layer 140 is flush with the surrounding surface 165 of the insulation layer 164 of the first circuit structure 160d to form multiple packaging devices 100d (only one is schematically shown in FIG. 3C) separated from each other. Here, the manufacturing of the fan-out packaging device 100d is completed.

Please refer to FIG. 3C and FIG. 3D at the same time. Through the manufacturing method of the packaging device, a packaging device 100e may also be formed, wherein viewing from a cross-section, the base layer 119 of an electronic unit 110e has a recess 116, wherein the recess 116 may be caused by singulation cutting the electronic unit 110a (as shown in the step of FIG. 3A), and the recess 116 may be a continuous surface with an inclined surrounding surface 131e of a buffer layer 130e, but not limited thereto.

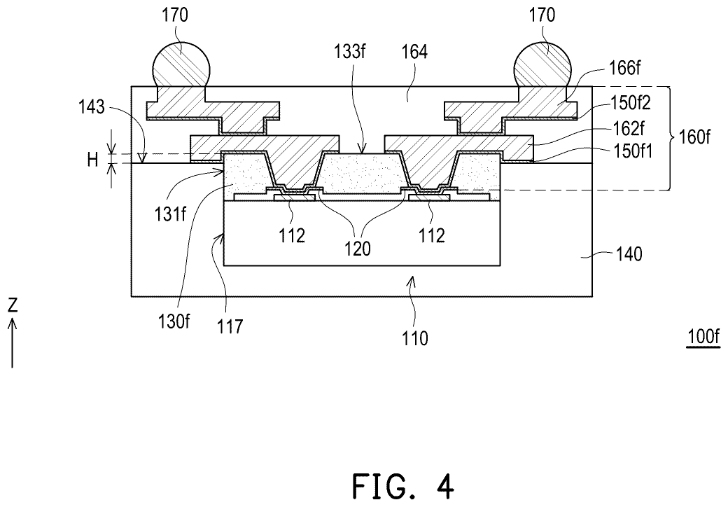

FIG. 4 to FIG. 10 are cross-sectional schematic views of a packaging devices according to multiple embodiments of the disclosure. Please refer to FIG. 1F and FIG. 4 first at the same time. A packaging device 100f of the embodiment is similar to the packaging device 100a of FIG. 1F. The difference between the two is that in the embodiment, a first metal layer 162f overlaps with at least part of a surrounding surface 131f of a buffer layer 130f. Specifically, the first metal layer 162f may extend to be disposed on the surrounding surface 131f of the buffer layer 130f, wherein there is a height difference H between a top surface 133f (that is, a first upper surface) of the buffer layer 130f and the surface 143 (that is, a second upper surface) of the insulation layer 140. In other words, the top surface 133f of the buffer layer 130f and the surface 143 of the insulation layer 140 are not coplanar, which can improve the reliability of the packaging device 100f. According to some embodiments, the height difference H may be greater than or equal to 1 μm and less than or equal to 10 μm, but not limited thereto. The surrounding surface 131f of the buffer layer 130f is flush with the surrounding surface 117 of the electronic unit 110. Furthermore, a first circuit structure 160f of the embodiment further includes the insulation layer 164 and a second metal layer 166f, wherein the second metal layer 166f is structurally and electrically connected to the first metal layer 162f, and the insulation layer 164 covers the first metal layer 162f, the second metal layer 166f, and the surface 143 of the insulation layer 140. In addition, a seed layer 150f1 is located between the first metal layer 162f and the conductive layer 120, between the first metal layer 162f and the buffer layer 130f, and between the first metal layer 162f and the insulation layer 140, and a part of a seed layer 150f2 is located between the second metal layer 166f and the first metal layer 162f. Here, the first circuit structure 160f is a fan-out circuit structure.

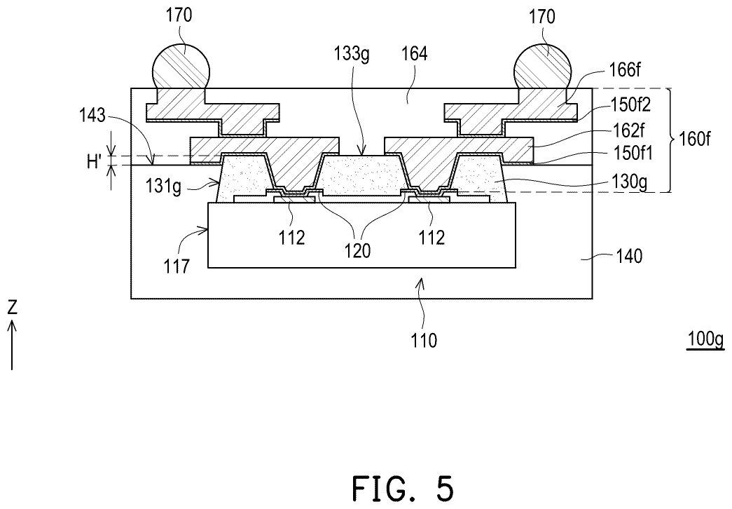

Please refer to FIG. 4 and FIG. 5 at the same time. A packaging device 100g of the embodiment is similar to the packaging device 100f of FIG. 4. The difference between the two is that in the embodiment, there is a height difference H′ between a top surface 133g (that is, a first upper surface) of a buffer layer 130g and the surface 143 (that is, the second upper surface) of the insulation layer 140, and a surrounding surface 131g of the buffer layer 130g is an inclined surface.

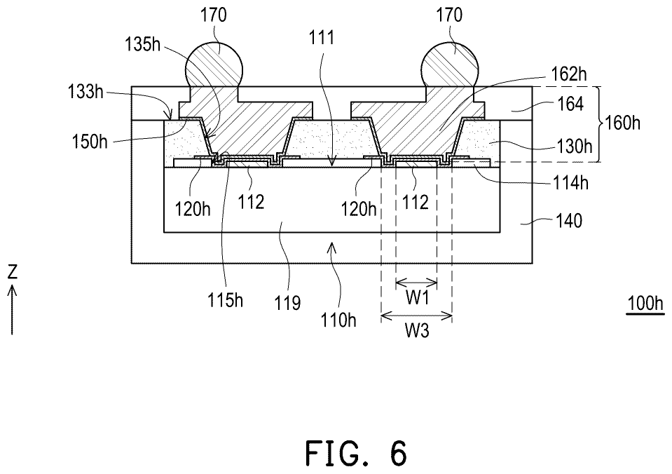

Please refer to FIG. 1F and FIG. 6 at the same time. A packaging device 100h of the embodiment is similar to the packaging device 100a of FIG. 1F. The difference between the two is that in the embodiment, a conductive layer 120h contacts the base layer 119 of an electronic unit 110h at a first opening 115h of a protective layer 114h. In an embodiment, the first opening 115h of the protective layer 114h exposes a part of the base layer 119 of the electronic unit 110h, and the conductive layer 120h extends into the first opening 115h and covers the base layer 119. In an embodiment, the width W1 of the pad 112 is less than a width W3 of a second opening 135h of a buffer layer 130h. The width W3 of the second opening 135h described here is the width W2 closest to the first opening 115h. In an embodiment, a seed layer 150h directly covers an inner wall of the second opening 135h of the buffer layer 130h and directly contacts the conductive layer 120h, wherein the seed layer 150h extends onto a top surface 133h of the buffer layer 130h away from of the electronic unit 110h and the surface 143 of the insulation layer 140. A first metal layer 162h of a first circuit structure 160h extends into the second opening 135h and the first opening 115h.

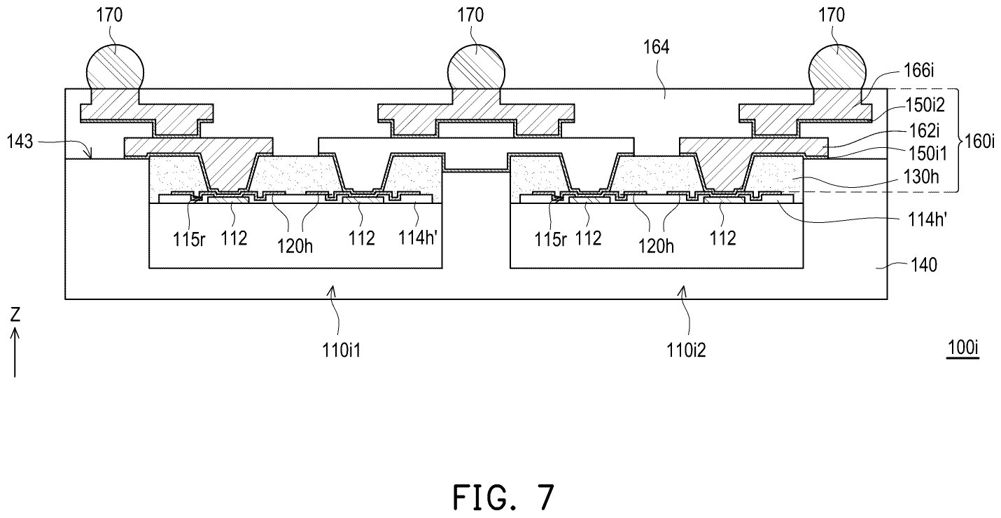

Please refer to FIG. 6 and FIG. 7 at the same time. A packaging device 100i of the embodiment is similar to the packaging device 100h of FIG. 6. The difference between the two is that in the embodiment, the packaging device 100i includes two electronic units 110i1 and 110i2, wherein the electronic units 110i1 and 11012 are electrically connected to each other through a first metal layer 162i of a first circuit structure 160i. Here, the electronic units 110i1 and 11012 are similar in design to the electronic unit 110h of FIG. 6, wherein a protective layer 114h′ has a recess 115r, and a part of the conductive layer 120h may extend into the recess 115r, so as to increase the bonding force between the film layers, but not limited thereto. In addition, the first circuit structure 160i of the embodiment further includes the insulation layer 164 and a second metal layer 166i, wherein the second metal layer 166i is structurally and electrically connected to the first metal layer 162i, and the insulation layer 164 covers the first metal layer 162i, the second metal layer 166i, and the surface 143 of the insulation layer 140. In addition, a seed layer 150i1 is located between the first metal layer 162i and the conductive layer 120, between the first metal layer 162i and the buffer layer 130h, and between the first metal layer 162i and the insulation layer 140, and a part of a seed layer 15012 is located between the second metal layer 166i and the first metal layer 162i. Here, the first circuit structure 160i is a fan-out circuit structure.

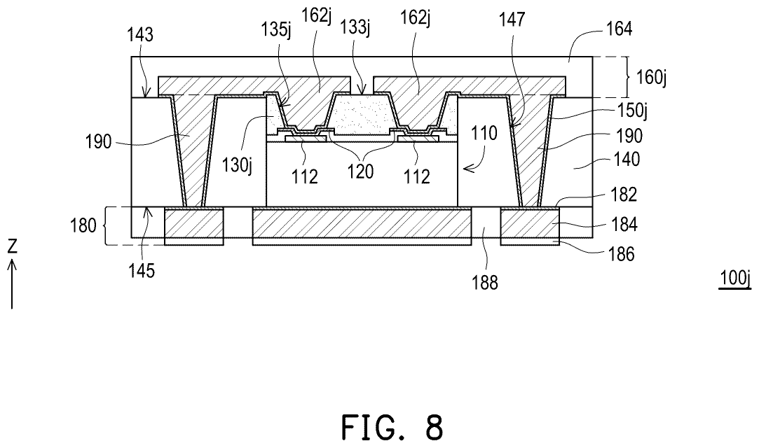

Please refer to FIG. 1F and FIG. 8 at the same time. A packaging device 100j of the embodiment is similar to the packaging device 100a of FIG. 1F. The difference between the two is that in the embodiment, the packaging device 100j further includes a second circuit structure 180 and a conductive via 190. A first circuit structure 160j and the second circuit structure 180 are respectively disposed on the surface 143 and the surrounding surface 141 of the insulation layer 140. The conductive via 190 penetrates the insulation layer 140 and electrically connects the first circuit structure 160j and the second circuit structure 180. According to some embodiments, in a cross-sectional schematic view, the conductive via 190 may be trapezoidal, inverted trapezoidal, rectangular, square, hourglass-shaped, any shape, or a combination of the above.

In detail, a seed layer 150j of the embodiment extends from a second opening 135j of a buffer layer 130j to be disposed on a top surface 133j of the buffer layer 130j, on the surface 143 of the insulation layer 140, and in a via 147. A first metal layer 162j of the first circuit structure 160j extends from the second opening 135j of the buffer layer 130j to be disposed on the top surface 133j of the buffer layer 130j and the surface 143 of the insulation layer 140, and the conductive via 190 structurally and electrically connects the first metal layer 162j of the first circuit structure 160j and a second metal layer 184 of the second circuit structure 180. The second circuit structure 180 further includes a seed layer 182, an insulation layer 188, and a contact portion 186, wherein the seed layer 182 directly contacts the conductive via 190 and the seed layer 150j, the second metal layer 184 is located between the seed layer 182 and the contact portion 186, and the insulation layer 188 covers the seed layer 182 and the second metal layer 184 to expose the contact portion 186. The packaging device 100j may contact other electronic units through the contact portion 186 of the second circuit structure 180. In an embodiment, the second circuit structure 180 may also be a heat sink, but not limited thereto.

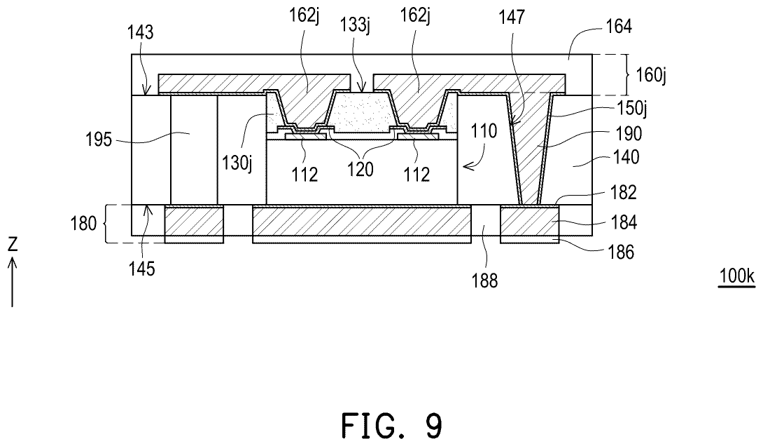

Please refer to FIG. 8 and FIG. 9 first at the same time. A packaging device 100k of the embodiment is similar to the packaging device 100j of FIG. 8. The difference between the two is that in the embodiment, the packaging device 100k further includes a buffer element 195 penetrating the insulation layer 140 and abutting the first circuit structure 160j and the second circuit structure 180. In an embodiment, the buffer element 195 is, for example, a high-side switch, a low-side switch, highly doped silicon, a copper block, or a conductive element, but not limited thereto. According to the above design, the reliability of the packaging device 100k can be improved. For example, the heat dissipation or electrical characteristics of the packaging device can be improved, but not limited thereto.

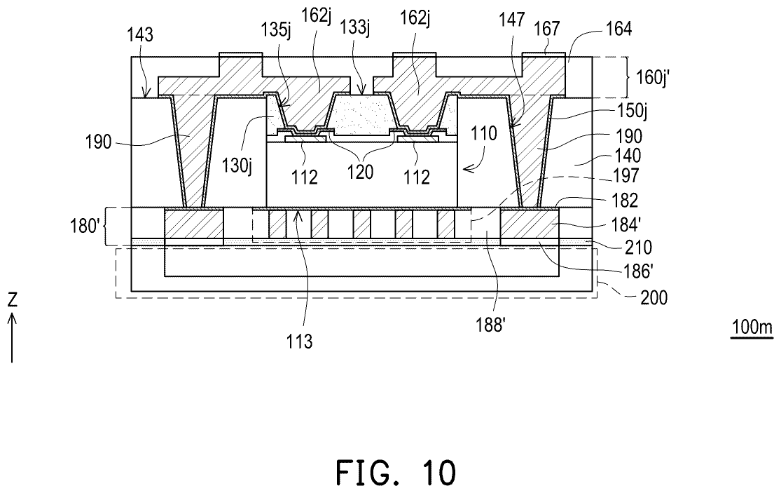

Please refer to FIG. 8 and FIG. 10 first at the same time. A packaging device 100m of the embodiment is similar to the packaging device 100j of FIG. 8. The difference between the two is that in the embodiment, the packaging device 100m further includes a heat dissipation element 197 disposed on the back surface 113 of the electronic unit 110. According to some embodiments, the heat dissipation element 197 may be embedded in an insulation layer 188′ of a second circuit structure 180′, but not limited thereto. Furthermore, the packaging device 100m of the embodiment further includes another packaging device 200 disposed on the second circuit structure 180′ through an intermediary layer 210 and electrically connected to a second metal layer 184′ of the second circuit structure 180′ through a contact portion 186′. In an embodiment, the intermediary layer 210 may be, for example, a heat dissipation material, but not limited thereto. In addition, a first circuit structure 160j′ of the embodiment further includes a contact portion 167, wherein the packaging device 100m may contact other external units through the contact portion 167 of the first circuit structure 160j′. The external unit may include a printed circuit board, an IC carrier board, or other suitable external units.

In summary, in the embodiments of the disclosure, the conductive layer is disposed on the pad, and the activity of the conductive layer is less than the activity of the pad, which means that the oxidative capacity of the conductive layer is less than the oxidative capacity of the pad, that is, the conductive layer is less susceptible to oxidation than the pad, which can effectively reduce the influence of the organic material on the pad to reduce/stabilize the contact resistance of the pad, thereby enabling the packaging device of the disclosure to have improved electrical reliability.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. A packaging device, comprising:
an electronic unit, comprising a pad;
a conductive layer, disposed on the pad;
a buffer layer, disposed on the conductive layer;
an insulation layer, surrounding the electronic unit and the buffer layer; and
a first circuit structure, electrically connected to the electronic unit, wherein a part of the conductive layer is located between the electronic unit and the buffer layer, and an activity of the conductive layer is less than an activity of the pad.

2. The packaging device according to claim 1, wherein the electronic unit comprises a protective layer, wherein the protective layer comprises a first opening to expose at least part of the pad, and the conductive layer covers the at least part of the pad.

3. The packaging device according to claim 2, wherein the buffer layer comprises a second opening overlapping with the first opening, and a first metal layer of the first circuit structure extends into the second opening and the first opening.

4. The packaging device according to claim 3, further comprising:
a seed layer, disposed between the first metal layer and the buffer layer and contacting the conductive layer.

5. The packaging device according to claim 3, wherein the first metal layer is disposed on the buffer layer, the first metal layer overlaps with at least part of a surrounding surface of the buffer layer, and there is a height difference between a first upper surface of the buffer layer and a second upper surface of the insulation layer.

6. The packaging device according to claim 2, wherein the conductive layer contacts a base layer of the electronic unit at the first opening.

7. The packaging device according to claim 1, wherein the buffer layer contacts a base layer of the electronic unit.

8. The packaging device according to claim 1, wherein the buffer layer has a top surface, a bottom surface, and a surrounding surface obliquely connecting the top surface and the bottom surface.

9. The packaging device according to claim 1, further comprising:
a second circuit structure, wherein the first circuit structure and the second circuit structure are respectively disposed on a first surface and a second surface of the insulation layer; and
a conductive via, penetrating the insulation layer and electrically connecting the first circuit structure and the second circuit structure.

10. The packaging device according to claim 9, further comprising:
a buffer element, penetrating the insulation layer and abutting the first circuit structure and the second circuit structure.

11. A manufacturing method of a packaging device, comprising:
providing an electronic unit comprising a pad;
forming a conductive layer on the pad;
forming a buffer layer on the conductive layer;
forming an insulation layer to surround the electronic unit and the buffer layer; and
forming a first circuit structure to be electrically connected to the electronic unit, wherein a part of the conductive layer is located between the electronic unit and the buffer layer, and an activity of the conductive layer is less than an activity of the pad.

12. The manufacturing method of the packaging device according to claim 11, further comprising:
forming a protective layer on the electronic unit before forming a conductive layer on the pad, wherein the protective layer comprises a first opening, and the first opening exposes at least part of the pad; and
forming the conductive layer on the pad, wherein the conductive layer covers the at least part of the pad.

13. The manufacturing method of the packaging device according to claim 12, further comprising:
forming a second opening overlapping with the first opening on the buffer layer before forming the insulation layer to surround the electronic unit and the buffer layer; and
extending a first metal layer of the first circuit structure into the second opening and the first opening when forming the first circuit structure.

14. The manufacturing method of the packaging device according to claim 13, further comprising:
forming a seed layer on the buffer layer and contacting the conductive layer before forming the first circuit structure.

15. The manufacturing method of the packaging device according to claim 12, wherein the first metal layer is disposed on the buffer layer, the first metal layer overlaps with at least part of a surrounding surface of the buffer layer, and there is a height difference between a first upper surface of the buffer layer and a second upper surface of the insulation layer.

16. The manufacturing method of the packaging device according to claim 12, wherein the conductive layer contacts a base layer of the electronic unit at the first opening.

17. The manufacturing method of the packaging device according to claim 12, wherein the buffer layer contacts a base layer of the electronic unit.

18. The manufacturing method of the packaging device according to claim 11, wherein the buffer layer has a top surface, a bottom surface, and a surrounding surface obliquely connecting the top surface and the bottom surface.

19. The manufacturing method of the packaging device according to claim 11, further comprising:
performing a grinding process after forming the insulation layer to surround the electronic unit and the buffer layer to expose a top surface of the buffer layer.

20. The manufacturing method of the packaging device according to claim 11, further comprising
forming a connector on the first circuit structure, wherein the connector is electrically connected to the first circuit structure.
